(19) United States
(12) Patent Application Publication
(10) Pub. No.: US 2026/0112971 A1
(43) Pub. Date: Apr. 23, 2026

(54) POWER CONVERTER AND METHOD OF CONTROLLING THE SAME

(71) Applicant: CHICONY POWER TECHNOLOGY CO., LTD., New Taipei City (TW)

(72) Inventor: Chen-Chi LIN, New Taipei City (TW)

(21) Appl. No.: 18/967,571

(22) Filed: Dec. 3, 2024

(30) Foreign Application Priority Data
Oct. 21, 2024 (TW) 113140035

(51) Int. Cl. H02M 3/158; H02M 1/00; H02M 1/08; H02M 3/00

(52) U.S. Cl. CPC H02M 3/158; H02M 1/0054; H02M 1/08; H02M 3/01

(57) ABSTRACT

A power converter includes a transformer, a resonant circuit, a first switch, a second switch, an input detection circuit, an output detection circuit, and a controller. The first switch and the second switch are jointly connected at a node, and the node is coupled to the resonant circuit to acquire a first output voltage information corresponding to an output voltage. The input detection circuit is coupled to the first switch to acquire an input voltage information according to an input voltage. The output detection circuit acquires a second output voltage information corresponding to the output voltage. The controller receives the first output voltage information, the second output voltage information, and the input voltage information to turn on or turn off the first switch and the second switch according to the first output voltage information, the second output voltage information, and the input voltage information.

### BACKGROUND

### Technical Field

The present disclosure relates to a power converter and a method of controlling the same, and more particularly to a power converter with minimized switching losses and a method of controlling the same.

### Description of Related Art

The statements in this section merely provide background information related to the present disclosure and do not necessarily constitute prior art.

A half-bridge DC converter is a power conversion structure that converts DC voltage into different DC voltages, which is mainly composed of two transistor switches, that is, switch components alternately repeatedly turn on and turn off to achieve the purpose of adjusting the voltage output. Moreover, an asymmetric half-bridge converter (AHB converter) has the characteristics of a small number of components, switch voltage clamping and soft switching, and therefore it is widely used in the field of medium and low power conversion. The half-bridge converter is controlled through pulse width modulation with asymmetric duty cycles to achieve soft switching of the half-bridge converter.

For the operation of the asymmetric half-bridge converter, when the load decreases, it will switch from a continuous conduction mode (CCM) or a critical conduction mode (CrM) to a discontinuous conduction mode (DCM), and therefore the reduced switching frequency in the DCM reduces switching losses and increases the conversion efficiency of the power supply.

Therefore, how to design a power converter and a method of controlling the same to minimize switching losses and increase the conversion efficiency of the power converter from converting the state where neither the high-side switch nor the low-side switch is turned on to the state where the high-side switch is turned on and the low-side switch is turned off, or the high-side switch is turned off and the low-side switch is turned on has become a critical topic in this field.

### SUMMARY

An objective of the present disclosure is to provide a power converter. The power converter includes a transformer, a resonant circuit, a first switch and a second switch, an input detection circuit, an output detection circuit, and a controller. The transformer includes a primary side and a secondary side. The primary side includes a primary-side winding and an auxiliary winding, and the secondary side includes a secondary-side winding. The resonant circuit is coupled to the primary-side winding, and the resonant circuit includes a resonant capacitor and a resonant inductor. The resonant inductor includes a magnetizing inductance and a leakage inductance. The first switch and the second switch are jointly connected at a node, and the node is coupled to the resonant circuit to acquire a first output voltage information corresponding to an output voltage of the power converter. The input detection circuit is coupled to the first switch to acquire an input voltage information according to an input voltage of the power converter. The output detection circuit includes the auxiliary winding to acquire a second output voltage information corresponding to the output voltage. The controller receives the first output voltage information, the second output voltage information, and the input voltage information to turn on or turn off the first switch and the second switch according to the first output voltage information, the second output voltage information, and the input voltage information.

In one embodiment, based on that the first switch and the second switch are turned off; when a difference between the input voltage information and the first output voltage information is greater than a difference between the first output voltage information and a ground voltage, the controller turns on the second switch and turns off the first switch; when the difference between the input voltage information and the first output voltage information is less than the difference between the first output voltage information and the ground voltage, the controller turns on the first switch and turns off the second switch.

In one embodiment, based on that the first switch and the second switch are turned off; when a difference between the input voltage information and the second output voltage information is greater than a difference between the second output voltage information and a ground voltage, the controller turns on the second switch and turns off the first switch; when the difference between the input voltage information and the second output voltage information is less than the difference between the second output voltage information and the ground voltage, the controller turns on the first switch and turns off the second switch.

In one embodiment, based on that the first switch and the second switch are turned off;

when a difference between the first output voltage information and a ground voltage is greater than a reference voltage, the controller turns on the first switch and turns off the second switch; when the difference between the first output voltage information and the ground voltage is less than the reference voltage, the controller turns on the second switch and turns off the first switch.

In one embodiment, based on that the first switch and the second switch are turned off;

when a difference between the second output voltage information and a ground voltage is greater than a reference voltage, the controller turns on the first switch and turns off the second switch; when the difference between the second output voltage information and the ground voltage is less than the reference voltage, the controller turns on the second switch and turns off the first switch.

In one embodiment, the input detection circuit includes a first resistor and a second resistor; the first resistor and the second resistor divide the input voltage to generate the input voltage information on the second resistor.

In one embodiment, a voltage ratio between the first output voltage information and the output voltage is equal to a turns ratio between the primary-side winding and the secondary-side winding.

In one embodiment, the output detection circuit further includes a third resistor and a fourth resistor, and the third resistor and the fourth resistor are coupled to the auxiliary winding; the third resistor and the fourth resistor divide an auxiliary voltage on the auxiliary winding to generate the second output voltage information on the fourth resistor; wherein a voltage ratio between the auxiliary voltage and the output voltage is equal to a turns ration between the auxiliary winding and the secondary-side winding.

In one embodiment, the controller includes a first differential amplifier, a second differential amplifier, and a comparator. The first differential amplifier receives the input voltage information and the first output voltage information, and amplifies a difference between the input voltage information and the first output voltage information to acquire a first voltage difference. The second differential amplifier receives the first output voltage information and the ground voltage, and amplifies a difference between the first output voltage information and the ground voltage to acquire a second voltage difference. The comparator receives the first voltage difference and the second voltage difference, and compares the first voltage difference with the second voltage difference to generate a control signal. When the control signal is in a high level, the control signal turns on the second switch and turns off the first switch; when the control signal is in a low level, the control signal turns on the first switch and turns off the second switch.

In one embodiment, the controller includes a first differential amplifier, a second differential amplifier, and a comparator. The first differential amplifier receives the input voltage information and the second output voltage information, and amplifies a difference between the input voltage information and the second output voltage information to acquire a first voltage difference. The second differential amplifier receives the second output voltage information and the ground voltage, and amplifies a difference between the second output voltage information and the ground voltage to acquire a second voltage difference. The comparator receives the first voltage difference and the second voltage difference, and compares the first voltage difference with the second voltage difference to generate a control signal. When the control signal is in a high level, the control signal turns on the second switch and turns off the first switch; when the control signal is in a low level, the control signal turns on the first switch and turns off the second switch.

In one embodiment, the controller includes a differential amplifier and a comparator. The differential amplifier receives the first output voltage information and a ground voltage, and amplifies a difference between the first output voltage information and the ground voltage to acquire a voltage difference. The comparator receives the voltage difference and the reference voltage, and compares the voltage difference with the reference voltage to generate a control signal. When the control signal is in a high level, the control signal turns on the second switch and turns off the first switch; when the control signal is in a low level, the control signal turns on the first switch and turns off the second switch.

In one embodiment, the controller includes a differential amplifier and a comparator. The differential amplifier receives the second output voltage information and a ground voltage, and amplifies a difference between the second output voltage information and the ground voltage to acquire a voltage difference. The comparator receives the voltage difference and the reference voltage, and compares the voltage difference with the reference voltage to generate a control signal. When the control signal is in a high level, the control signal turns on the second switch and turns off the first switch; when the control signal is in a low level, the control signal turns on the first switch and turns off the second switch.

In one embodiment, the controller further includes a register. The register receives the control signal, and stores a high level or a low level of the control signal; when the register is triggered, the high level or the low level of the control signal controls the first switch and the second switch to be turned on and turned off.

Another objective of the present disclosure is to provide a method of controlling a power converter. The power converter includes a first switch and a second switch. The method includes steps of: detecting an input voltage and an output voltage of the power converter based on that the input voltage and the output voltage are varied; acquiring an input voltage information corresponding to the input voltage and acquiring an output voltage information corresponding to the output voltage; calculating a difference between the input voltage information and the output voltage information to be a first voltage difference and calculating a difference between the output voltage information and a ground voltage to be a second voltage difference; turning on the second switch and turning off the first switch when the first voltage difference is greater than the second voltage difference; turning on the first switch and turning off the second switch when the first voltage difference is less than the second voltage difference.

In one embodiment, a voltage ratio between the output voltage information and the output voltage is equal to a turns ratio between a primary-side winding and a secondary-side winding of a transformer of the power converter, or a voltage ratio between the output voltage information and the output voltage is equal to a turns ratio between an auxiliary winding of the transformer and the secondary-side winding.

Further another objective of the present disclosure is to provide a method of controlling a power converter. The power converter includes a first switch and a second switch. The method includes steps of: detecting an output voltage of the power converter based on that the output voltage is varied and an input voltage of the power converter is fixed; acquiring an output voltage information corresponding to the output voltage; calculating a difference between the output voltage information and a ground voltage to be a voltage difference; turning on the first switch and turning off the second switch when the voltage difference is greater than a reference voltage; turning on the second switch and turning off the first switch when the voltage difference is less than the reference voltage.

In one embodiment, a voltage ratio between the output voltage information and the output voltage is equal to a turns ratio between a primary-side winding and a secondary-side winding of a transformer of the power converter, or a voltage ratio between the output voltage information and the output voltage is equal to a turns ratio between an auxiliary winding of the transformer and the secondary-side winding.

Accordingly, the present disclosure has the following features and advantages: 1. Based on that the output voltage and the input voltage of the power converter are varied, by determining the relationship between the output voltage and the input voltage to minimize switching losses and increase the conversion efficiency of the power converter from converting the state where neither the first switch nor the second switch is turned on to the state where the first switch is turned on and the second switch is turned off, or the first switch is turned off and the second switch is turned under the DCM; 2. Based on that the output voltage is varied and the input voltage is fixed, by determining the relationship between the output voltage and the reference voltage to minimize switching losses and increase the conversion efficiency of the power converter from converting the state where neither the first switch nor the second switch is turned on to the state where the first switch is turned on and the second switch is turned off, or the first switch is turned off and the second switch is turned under the DCM.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a block circuit diagram of a power converter according to the present disclosure.

FIG. 2 is a block diagram of a controller according to a first embodiment of the present disclosure.

FIG. 3 is a block diagram of the controller further including a register according to a first embodiment of the present disclosure.

FIG. 4 is a block diagram of the controller according to a second embodiment of the present disclosure.

FIG. 5 is a block diagram of the controller according to a third embodiment of the present disclosure.

FIG. 6 is a block diagram of the controller according to a fourth embodiment of the present disclosure.

FIG. 7 is a detailed block diagram of the controller according to the first embodiment of the present disclosure.

FIG. 8 is a detailed block diagram of the controller according to the second embodiment of the present disclosure.

FIG. 9 is a detailed block diagram of the controller according to the third embodiment of the present disclosure.

FIG. 10 is a detailed block diagram of the controller according to the fourth embodiment of the present disclosure.

FIG. 11 is a flowchart of a method of controlling the power converter according to a first embodiment of the present disclosure.

FIG. 12 is a flowchart of a method of controlling the power converter according to a second embodiment of the present disclosure.

### DETAILED DESCRIPTION

Reference will now be made to the drawing figures to describe the present disclosure in detail. It will be understood that the drawing figures and exemplified embodiments of present disclosure are not limited to the details thereof.

The structures, proportions, sizes, and number of components shown in the drawings attached to the present disclosure are only used to match the content in the present disclosure, for those who are familiar with this technology to understand and read, and are not used to limit the implementation of the present disclosure. Any modification of structure, change of proportional relationship or adjustment of size shall fall within the scope covered by the technical content disclosed in the present disclosure, provided that it does not affect the effect and purpose of the present disclosure.

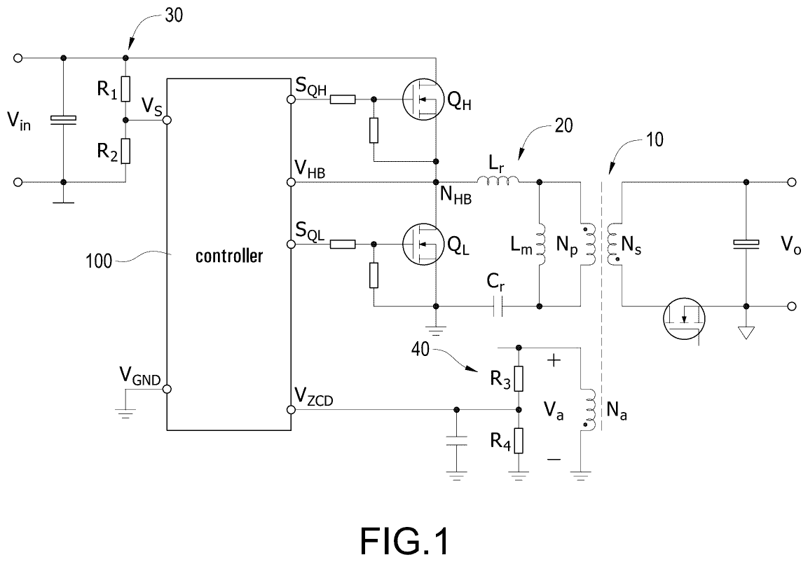

Please refer to FIG. 1, which shows a block circuit diagram of a power converter according to the present disclosure. The power converter includes a transformer 10, a resonant circuit 20, a first switch Q_{H} and a second switch Q_{L}, an input detection circuit 30, an output detection circuit 40, and a controller 100. The transformer 10 includes a primary side and a secondary side. The primary side includes a primary-side winding Np and an auxiliary winding Na, and the secondary side includes a secondary-side winding Ns.

The resonant circuit 20 is coupled to the primary-side winding Np. The resonant circuit includes a resonant capacitor Cr and a resonant inductor. The resonant inductor includes a magnetizing inductance Lm and a leakage inductance Lr.

The first switch Q_{H} and the second switch Q_{L} are jointly connected at a node N_{HB}. Incidentally, in this embodiment, the first switch Q_{H} refers to a high-side switch, and the second switch Q_{L} refers to a low-side switch. The node N_{HB} is coupled to the resonant circuit 20 to acquire a first output voltage information V_{HB} corresponding to an output voltage Vo of the power converter, that is, the first output voltage information V_{HB} is generated on the node N_{HB}. The so-called “first output voltage information V_{HB} corresponding to the output voltage Vo” as mentioned above means that there is a positive correlation between the first output voltage information V_{HB} and the output voltage Vo. For example, there is a voltage ratio between the low output voltage Vo and the high first output voltage information V_{HB}. In other words, by acquiring the high first output voltage information V_{HB}, the relevant information of the low output voltage Vo can be acquired. In particular, a voltage ratio between the first output voltage information V_{HB} and the output voltage Vo is equal to a turns ratio between the primary-side winding Np and the secondary-side winding Ns, that is, V_{HB}/Vo=Np/N_{S}. The relevant Ns disclosures below have the same meaning and are therefore not repeated.

The input detection circuit 30 is coupled to the first switch Q_{H} to acquire an input voltage information V_{S} corresponding to an input voltage Vin of the power converter. The input detection circuit 30 is used to detect electrical values of input power of the power converter. For example, if the input detection circuit 30 is used to detect input voltage, the input detection circuit 30 is an input voltage detection circuit; if it is used to detect input current, the input detection circuit 30 is an input current detection circuit, and so on. As shown in FIG. 1, the input detection circuit 30 includes a first resistor R₁ and a second resistor R₂. The first resistor R₁ and the second resistor R₂ divide the input voltage Vin to generate the input voltage information V_{S} on the second resistor R₂, that is,

$${V}_{S} = Vin \times \frac{{R}_{2}}{{R}_{1} + {R}_{2}} .$$

However, the present disclosure is not limited to this embodiment. All circuits and devices capable of acquiring voltage information corresponding to the input voltage Vin should be included within the scope of the present disclosure.

The output detection circuit 40 includes an auxiliary winding Na to acquire a second output voltage information V_{ZCD} corresponding to the output voltage Vo. The output detection circuit further includes a third resistor R₃ and a fourth resistor R₄. The third resistor R₃ and the fourth resistor R₄ are coupled to the auxiliary winding Na. The third resistor R₃ and the fourth resistor R₄ divide an auxiliary voltage Va on the auxiliary winding Na to generate the second output voltage information V_{ZCD} on the fourth resistor R₄, that is,

$${V}_{ZCD} = Va \times \frac{{R}_{4}}{{R}_{3} + {R}_{4}} .$$

In particular, a voltage ratio between the auxiliary voltage Va and the output voltage Vo is equal to a turns ratio between the auxiliary winding Na and the secondary-side winding Ns, that is,

$$\frac{Va}{Vo} = \frac{Na}{Ns} ,$$

and therefore

$${V}_{ZCD} = Vo \times \frac{Na}{Ns} \times \frac{{R}_{4}}{{R}_{3} + {R}_{4}} .$$

However, the present disclosure is not limited to this embodiment. All circuits and devices capable of acquiring voltage information corresponding to the output voltage Vo should be included within the scope of the present disclosure.

The controller 100 receives the first output voltage information V_{HB}, the second output voltage information V_{ZCD}, and the input voltage information V_{S} to turn on or turn off the first switch Q_{H} and the second switch Q_{L} according to the first output voltage information V_{HB}, the second output voltage information V_{ZCD}, and the input voltage information V_{S}. Specific operation descriptions will be detailed later.

Based on that the first switch Q_{H} and the second switch Q_{L} are turned off, when a difference between the input voltage information V_{S} and the first output voltage information V_{HB} is greater than a difference between the first output voltage information V_{HB} and a ground voltage V_{GND}, the controller 100 turns on the second switch Q_{L} and turns off the first switch Q_{H}. On the contrary, when the difference between the input voltage information V_{S} and the first output voltage information V_{HB} is less than the difference between the first output voltage information V_{HB} and the ground voltage V_{GND}, the controller 100 turns on the first switch Q_{H} and turns off the second switch Q_{L}.

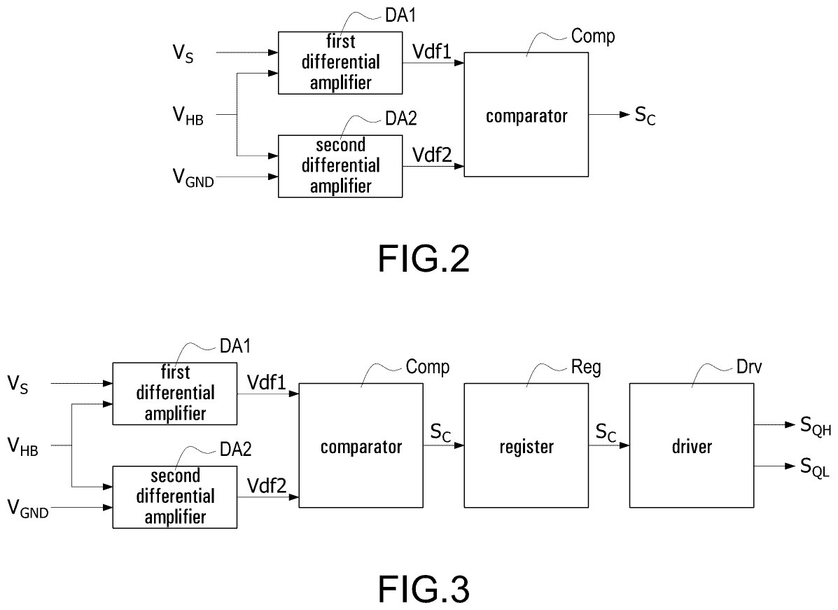

Specifically, please refer to FIG. 2, which shows a block diagram of a controller according to a first embodiment of the present disclosure. The controller 100 includes a first differential amplifier DA1, a second differential amplifier DA2, and a comparator Comp. The first differential amplifier DA1 receives the input voltage information V_{S} and the first output voltage information V_{HB}, and amplifies a difference between the input voltage information V_{S} and the first output voltage information V_{HB} to acquire a first voltage difference Vdf1. The second differential amplifier DA2 receives the first output voltage information V_{HB} and the ground voltage V_{GND}, and amplifies a difference between the first output voltage information V_{HB} and the ground voltage V_{GND} to acquire a second voltage difference Vdf2. The comparator Comp receives the first voltage difference Vdf1 and the second voltage difference Vdf2, and compares the first voltage difference Vdf1 with the second voltage difference Vdf2 to generate a control signal S_{C}. When the control signal S_{C} is in a high level, the control signal S_{C} turns on the second switch Q_{L} and turns off the first switch Q_{H}. On the contrary, when the control signal S_{C} is in a low level, the control signal S_{C} turns on the first switch Q_{H} and turns off the second switch Q_{L}.

Moreover, please refer to FIG. 3, which shows a block diagram of the controller further including a register according to a first embodiment of the present disclosure. Compared with FIG. 2, the embodiment shown in FIG. 3 further includes a register Reg. The register Reg receives the control signal S_{C}, and stores a high level or a low level of the control signal S_{C}. In particular, when the register Reg is triggered, the high level or the low level of the control signal S_{C} is used to control the first switch Q_{H} and the second switch Q_{L} to be turned on and turned off. In one embodiment, the register Reg is a flip flop (FF), for example, but not limited to, a D flip flop, that is, the register Reg may be a RS flip flop, JK flip flop, T flip flop, and so on. All basic logic units or analog circuits that can be used to form sequential logic circuits and various complex digital systems should be included in the scope of the present disclosure.

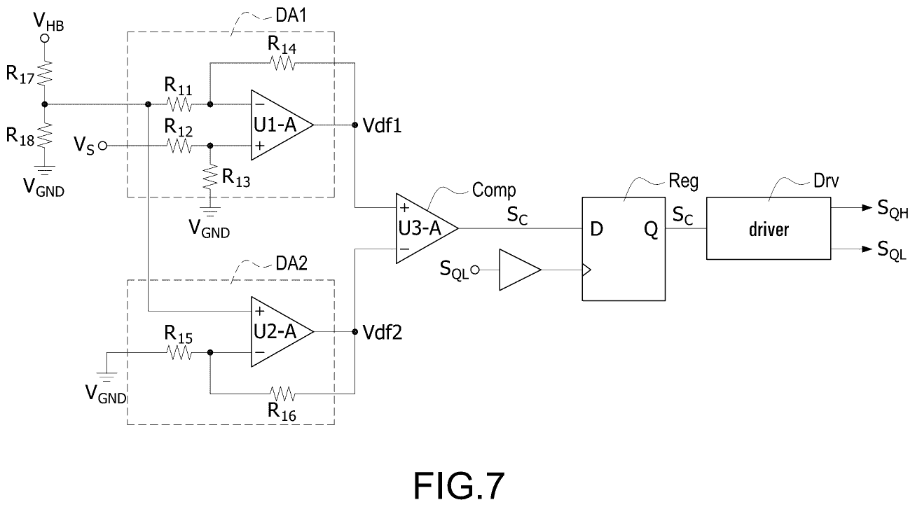

More specifically, please refer to FIG. 7, which shows a detailed block diagram of the controller according to the first embodiment of the present disclosure. The first differential amplifier DA1 shown in FIG. 2 includes an amplifier U1-A and a plurality of resistors R₁, R₁₂, R₁₃, R₁₄, the second differential amplifier DA2 includes an amplifier U2-A and a plurality of resistors R₁₅, R₁₆, and the comparator Comp includes a comparator U3-A. For convenience of explanation, it is assumed that a resistance of the resistor Ru is the same as a resistance of the resistor R₁₂, and a resistance of the resistor R₁₃ is the same as a resistance of the resistor R₁₄. Moreover, it is assumed that the first output voltage information V_{HB} is directly connected to an inverting input terminal of the amplifier U1-A, that is, without be divided by resistors R₁₇, R₁₈, and the input voltage information V_{S} is connected to a non-inverting input terminal of the amplifier U1-A. Therefore, the first voltage difference Vdf1 can be acquired:

$$Vdf 1 = \frac{{R}_{4}}{{R}_{11}} \times ( Vs - {V}_{HB} ) .$$

In addition, the first output voltage information V_{HB} is connected to a non-inverting input terminal of the amplifier U2-A, and the ground voltage V_{GND} is connected to an inverting input terminal of the amplifier U2-A. Therefore, the second voltage difference Vdf2 can be acquired:

$$Vdf 2 = ( 1 + \frac{{R}_{16}}{{R}_{15}} ) \times {V}_{HB} .$$

In addition, a non-inverting input terminal and an inverting input terminal of the comparator Comp are respectively connected to the first voltage difference Vdf1 and the second voltage difference Vdf2, and the comparator Comp compares the first voltage difference Vdf1 with the second voltage difference Vdf2. When the first voltage difference Vdf1 is greater than the second voltage difference Vdf2, the comparator Comp outputs the control signal S_{C} with a high level. On the contrary, when the first voltage difference Vdf1 is less than the second voltage difference Vdf2, the comparator Comp outputs the control signal S_{C} with a low level. In other words, when a difference between the input voltage information V_{S} and the first output voltage information V_{HB} is greater than a difference between the first output voltage information V_{HB} and the ground voltage V_{GND}, it means that the first voltage difference Vdf1 is greater than the second voltage difference Vdf2, and therefore the comparator Comp outputs the control signal S_{C} with the high level to the driver Drv through the driven register Reg (for example, but not limited to, the D flip flop). Therefore, by the circuit design of the driver Drv, the driver Drv outputs a second switch control signal S_{QL} with a high level and a first switch control signal S_{QH} with a low level to respectively turn on the second switch Q_{L} and turn off the first switch Q_{H}. On the contrary, when the difference between the input voltage information V_{S} and the first output voltage information V_{HB} is less than the difference between the first output voltage information V_{HB} and the ground voltage V_{GND}, it means that the first voltage difference Vdf1 is less than the second voltage difference Vdf2, and therefore the comparator Comp outputs the control signal S_{C} with the low level to the driver Drv through the driven register Reg (for example, but not limited to, the D flip flop) to the driver Drv. Therefore, by the circuit design of the driver Drv, the driver Drv outputs the first switch control signal S_{QH} with a high level and the second switch control signal S_{QL} with a low level to respectively turn on the first switch Q_{H} and turn off the second switch Q_{L}. Incidentally, in one embodiment, a clock input of the register Reg (for example, the D flip-flop) receives the second switch control signal S_{QL} delayed by a buffer, and therefore the register Reg can store the comparison result of the comparator Comp when the second switch Q_{L} changes from being turned on to being turned off, and then the stored data are transmitted to the driver Drv to decide a timing for outputting the first switch control signal S_{QH} and the second switch control signal S_{QL}.

Based on that the first switch Q_{H} and the second switch Q_{L} are turned off, when a difference between the input voltage information V_{S} and the second output voltage information V_{ZCD} is greater than a difference between the second output voltage information V_{ZCD} and the ground voltage V_{GND}, the controller 100 turns on the second switch Q_{L} and turns off the first switch Q_{H}. On the contrary, when the difference between the input voltage information V_{S} and the second output voltage information V_{ZCD} is less than the difference between the second output voltage information V_{ZCD} and the ground voltage V_{GND}, the controller 100 turns on the first switch Q_{H} and turns off the second switch Q_{L}.

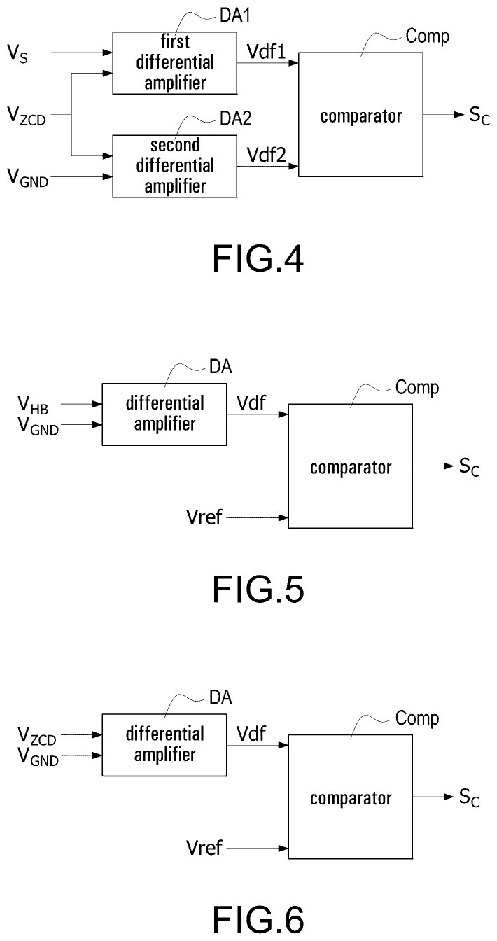

Specifically, please refer to FIG. 4, which shows a block diagram of the controller according to a second embodiment of the present disclosure. The controller 100 includes a first differential amplifier DA1, a second differential amplifier DA2, and a comparator Comp. The first differential amplifier DA1 receives the input voltage information V_{S} and the second output voltage information V_{ZCD}, and amplifies a difference between the input voltage information V_{S} and the second output voltage information V_{ZCD} to acquire a first voltage difference Vdf1. The second differential amplifier DA2 receives the second output voltage information V_{ZCD} and the ground voltage V_{GND}, and amplifies a difference between the second output voltage information V_{ZCD} and the ground voltage V_{GND} to acquire a second voltage difference Vdf2. The comparator Comp receives the first voltage difference Vdf1 and the second voltage difference Vdf2, and compares the first voltage difference Vdf1 with the second voltage difference Vdf2 to generate a control signal S_{C}. When the control signal S_{C} is in a high level, the control signal S_{C} turns on the second switch Q_{L} and turns off the first switch Q_{H}. On the contrary, when the control signal S_{C} is in a low level, the control signal S_{C} turns on the first switch Q_{H} and turns off the second switch Q_{L}.

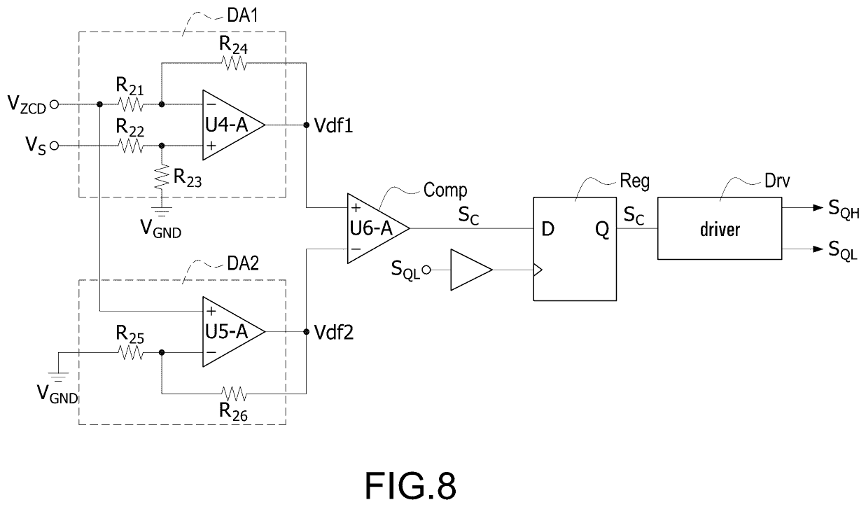

More specifically, please refer to FIG. 8, which shows a detailed block diagram of the controller according to the second embodiment of the present disclosure. The first differential amplifier DA1 shown in FIG. 4 includes an amplifier U4-A and a plurality of resistors R₂₁, R₂₂, R₂₃, R₂₄, the second differential amplifier DA2 includes an amplifier U5-A and a plurality of resistors R₂₅, R₂₆, and the comparator Comp includes a comparator U6-A. For convenience of explanation, it is assumed that a resistance of the resistor R₂₁ is the same as a resistance of the resistor R₂₂, and a resistance of the resistor R₂₃ is the same as a resistance of the resistor R₂₄. Moreover, the second output voltage information V_{ZCD} is connected to an inverting input terminal of the amplifier U4-A, and the input voltage information V_{S} is connected to a non-inverting input terminal of the amplifier U4-A. Therefore, the first voltage difference Vdf1 can be acquired:

$$Vdf 1 = \frac{{R}_{24}}{{R}_{21}} \times ( Vs - {V}_{ZCD} ) .$$

In addition, the second output voltage information V_{ZCD} is connected to a non-inverting input terminal of the amplifier U5-A, and the ground voltage V_{GND} is connected to an inverting input terminal of the amplifier U5-A. Therefore, the second voltage difference Vdf2 can be acquired:

$$Vdf 2 = ( 1 + \frac{{R}_{26}}{{R}_{25}} ) \times {V}_{ZCD} .$$

In addition, a non-inverting input terminal and an inverting input terminal of the comparator Comp are respectively connected to the first voltage difference Vdf1 and the second voltage difference Vdf2, and the comparator Comp compares the first voltage difference Vdf1 with the second voltage difference Vdf2. When the first voltage difference Vdf1 is greater than the second voltage difference Vdf2, the comparator Comp outputs the control signal S_{C} with a high level. On the contrary, when the first voltage difference Vdf1 is less than the second voltage difference Vdf2, the comparator Comp outputs the control signal S_{C} with a low level. In other words, when a difference between the input voltage information V_{S} and the second output voltage information V_{ZCD} is greater than a difference between the second output voltage information V_{ZCD} and the ground voltage V_{GND}, it means that the first voltage difference Vdf1 is greater than the second voltage difference Vdf2, and therefore the comparator Comp outputs the control signal S_{C} with the high level to the driver Drv through the driven register Reg. Therefore, by the circuit design of the driver Drv, the driver Drv outputs a second switch control signal S_{QL} with a high level and a first switch control signal S_{QH} with a low level to respectively turn on the second switch Q_{L} and turn off the first switch Q_{H}. On the contrary, when the difference between the input voltage information V_{S} and the second output voltage information V_{ZCD} is less than the difference between the second output voltage information V_{ZCD} and the ground voltage V_{GND}, it means that the first voltage difference Vdf1 is less than the second voltage difference Vdf2, and therefore the comparator Comp outputs the control signal S_{C} with the low level to the driver Drv through the driven register Reg. Therefore, by the circuit design of the driver Drv, the driver Drv outputs the first switch control signal S_{QH} with a high level and the second switch control signal S_{QL} with a low level to respectively turn on the first switch Q_{H} and turn off the second switch Q_{L}.

Based on that the first switch Q_{H} and the second switch Q_{L} are turned off, when a difference between the first output voltage information V_{HB} and the ground voltage V_{GND} is greater than a reference voltage Vref, the controller 100 turns on the first switch Q_{H} and turns off the second switch Q_{L}. On the contrary, when the difference between the first output voltage information V_{HB} and the ground voltage V_{GND} is less than the reference voltage Vref, the controller 100 turns on the second switch Q_{L} and turns off the first switch Q_{H}.

Specifically, please refer to FIG. 5, which shows a block diagram of a controller according to a third embodiment of the present disclosure. The controller 100 includes a differential amplifier DA and a comparator Comp. The differential amplifier DA receives the first output voltage information V_{HB} and the ground voltage V_{GND}, and amplifies a difference between the first output voltage information V_{HB} and the ground voltage V_{GND} to acquire a voltage difference PVDF. The comparator Comp receives the voltage difference Vdf and a reference voltage Vref, and compares the voltage difference Vdf with the reference voltage Vref to generate a control signal S_{C}. When the control signal S_{C} is in a high level, the control signal S_{C} turns on the second switch Q_{L} and turns off the first switch Q_{H}. On the contrary, when the control signal S_{C} is in a low level, the control signal S_{C} turns on the first switch Q_{H} and turns off the second switch Q_{L}.

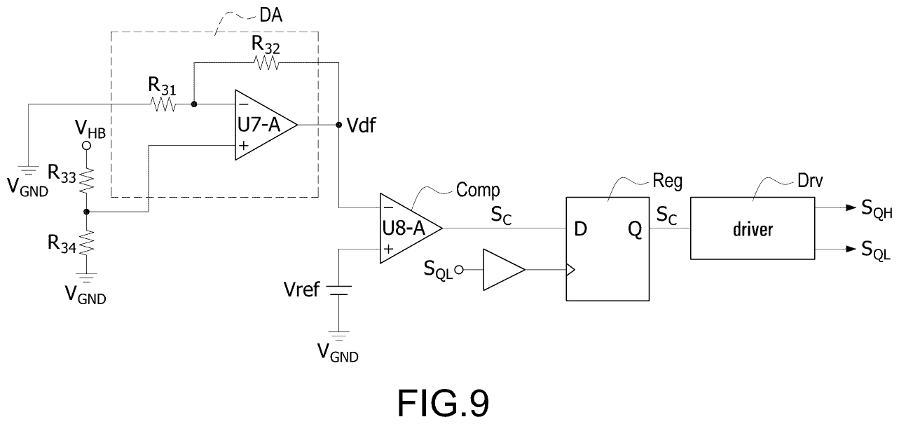

More specifically, please refer to FIG. 9, which shows a detailed block diagram of the controller according to the third embodiment of the present disclosure. The differential amplifier DA shown in FIG. 5 includes an amplifier U7-A and a plurality of resistors R₃₁, R₃₂, and the comparator Comp includes a comparator U8-A. For convenience of explanation, it is assumed that the first output voltage information V_{HB} is directly connected to a non-inverting input terminal of the amplifier U7-A, that is, without be divided by resistors R₃₃, R₃₄, and the ground voltage V_{GND} is connected to an inverting input terminal of the amplifier U7-A. Therefore, the voltage difference Vdf can be acquired:

$$Vdf = ( 1 + \frac{{R}_{32}}{{R}_{31}} ) \times {V}_{HB} .$$

In addition, an inverting input terminal and a non-inverting input terminal of the comparator Comp are respectively connected to the voltage difference Vdf and the reference voltage Vref, and the comparator Comp compares the voltage difference Vdf with the reference voltage Vref. When the voltage difference Vdf is greater than the reference voltage Vref, the comparator Comp outputs the control signal S_{C} with a low level. On the contrary, when the voltage difference Vdf is less than the reference voltage Vref, the comparator Comp outputs the control signal S_{C} with a high level. In other words, when a difference between the first output voltage information V_{HB} and the ground voltage V_{GND} is greater than the reference voltage Vref, it means that the voltage difference Vdf is greater than the reference voltage Vref, and therefore the comparator Comp outputs the control signal S_{C} with the low level to the driver Drv through the driven register Reg. Therefore, by the circuit design of the driver Drv, the driver Drv outputs a first switch control signal S_{QH} with a high level and a second switch control signal S_{QL} with a low level to respectively turn on the first switch Q_{H} and turn off the second switch Q_{L}. On the contrary, when the difference between the first output voltage information V_{HB} and the ground voltage V_{GND} is less than the reference voltage Vref, it means that the voltage difference Vdf is less than the reference voltage Vref, and therefore the comparator Comp outputs the control signal S_{C} with the high level to the driver Drv through the driven register Reg. Therefore, by the circuit design of the driver Drv, the driver Drv outputs a second switch control signal S_{QL} with a high level and a first switch control signal S_{QH} with a low level to respectively turn on the second switch Q_{L} and turn off the first switch Q_{H}.

Based on that the first switch Q_{H} and the second switch Q_{L} are turned off, when a difference between the second output voltage information V_{ZCD} and the ground voltage V_{GND} is greater than a reference voltage Vref, the controller 100 turns on the first switch Q_{H} and turns off the second switch Q_{L}. On the contrary, when the difference between the second output voltage information V_{ZCD} and the ground voltage V_{GND} is less than the reference voltage Vref, the controller 100 turns on the second switch Q_{L} and turns off the first switch Q_{H}.

Specifically, please refer to FIG. 6, which shows a block diagram of a controller according to a fourth embodiment of the present disclosure. The controller 100 includes a differential amplifier DA and a comparator Comp. The differential amplifier DA receives the second output voltage information V_{ZCD} and the ground voltage V_{GND}, and amplifies a difference between the second output voltage information V_{ZCD} and the ground voltage V_{GND} to acquire a voltage difference Vdf. The comparator Comp receives the voltage difference Vdf and a reference voltage Vref, and compares the voltage difference Vdf with the reference voltage Vref to generate a control signal S_{C}. When the control signal S_{C} is in a high level, the control signal S_{C} turns on the second switch Q_{L} and turns off the first switch Q_{H}. On the contrary, when the control signal S_{C} is in a low level, the control signal S_{C} turns on the first switch Q_{H} and turns off the second switch Q_{L}.

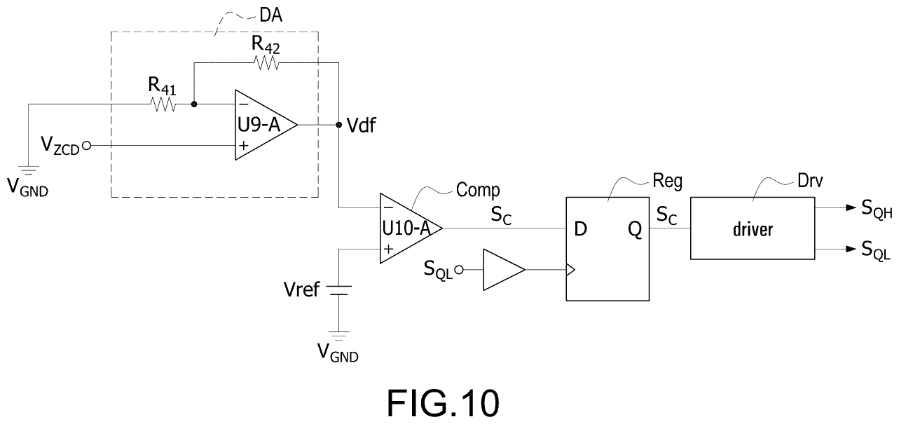

More specifically, please refer to FIG. 10, which shows a detailed block diagram of the controller according to the fourth embodiment of the present disclosure. The differential amplifier DA shown in FIG. 6 includes an amplifier U9-A and a plurality of resistors R₄₁, R₄₂, and the comparator Comp includes a comparator U10-A. The second output voltage information V_{ZCD} is connected to a non-inverting input terminal of the amplifier U9-A, and the ground voltage V_{GND} is connected to an inverting input terminal of the amplifier U9-A. Therefore, the voltage difference Vdf can be acquired:

$$Vdf = ( 1 + \frac{{R}_{42}}{{R}_{41}} ) \times {V}_{ZCD} .$$

In addition, an inverting input terminal and a non-inverting input terminal of the comparator Comp are respectively connected to the voltage difference Vdf and the reference voltage Vref, and the comparator Comp compares the voltage difference Vdf with the reference voltage Vref. When the voltage difference Vdf is greater than the reference voltage Vref, the comparator Comp outputs the control signal S_{C} with a low level. On the contrary, when the voltage difference Vdf is less than the reference voltage Vref, the comparator Comp outputs the control signal S_{C} with a high level. In other words, when a difference between the second output voltage information V_{ZCD} and the ground voltage V_{GND} is greater than the reference voltage Vref, it means that the voltage difference Vdf is greater than the reference voltage Vref, and therefore the comparator Comp outputs the control signal S_{C} with the low level to the driver Drv through the driven register Reg. Therefore, by the circuit design of the driver Drv, the driver Drv outputs a first switch control signal S_{QH} with a high level and a second switch control signal S_{QL} with a low level to respectively turn on the first switch Q_{H} and turn off the second switch Q_{L}. On the contrary, when the difference between the second output voltage information V_{ZCD} and the ground voltage V_{GND} is less than the reference voltage Vref, it means that the voltage difference Vdf is less than the reference voltage Vref, and therefore the comparator Comp outputs the control signal S_{C} with the high level to the driver Drv through the driven register Reg. Therefore, by the circuit design of the driver Drv, the driver Drv outputs a second switch control signal S_{QL} with a high level and a first switch control signal S_{QH} with a low level to respectively turn on the second switch Q_{L} and turn off the first switch Q_{H}.

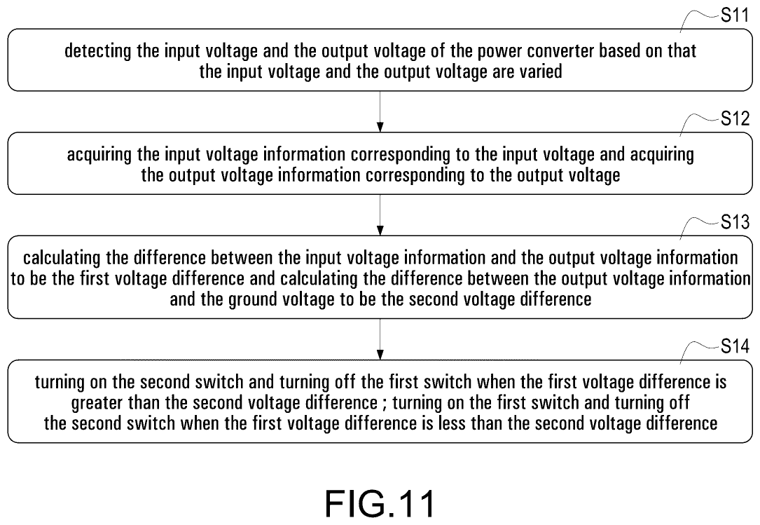

Please refer to FIG. 11, which shows a flowchart of a method of controlling the power converter according to a first embodiment of the present disclosure. The power converter includes a first switch Q_{H} and a second switch Q_{L}. The control method includes steps of: first, detecting an input voltage Vin and an output voltage Vo of the power converter based on that the input voltage Vin and the output voltage Vo are varied (step S11). Afterward, acquiring an input voltage information V_{S} corresponding to the input voltage Vin and acquiring an output voltage information V_{HB}/V_{ZCD} corresponding to the output voltage Vo (step S12). Afterward, calculating a difference between the input voltage information V_{S} and the output voltage information V_{HB}/V_{ZCD} to be a first voltage difference Vdf1 and calculating a difference between the output voltage information V_{HB}/V_{ZCD} and a ground voltage V_{GND} to be a second voltage difference Vdf2 (step S13). Finally, turning on the second switch Q_{L} and turning off the first switch Q_{H} when the first voltage difference Vdf1 is greater than the second voltage difference Vdf2; turning on the first switch Q_{H} and turning off the second switch Q_{L} when the first voltage difference Vdf1 is less than the second voltage difference Vdf2 (step S14).

Incidentally, a voltage ratio between the output voltage information V_{HB} and the output voltage Vo is equal to a turns ratio between a primary-side winding Np and a secondary-side winding Ns of a transformer 10 of the power converter, or a voltage ratio between the output voltage information V_{ZCD} and the output voltage Vo is equal to a turns ratio between an auxiliary winding Na of the transformer and the secondary-side winding Ns. As for the specific circuit structure and operation of the power converter, please refer to the previous disclosure and will not be repeated here.

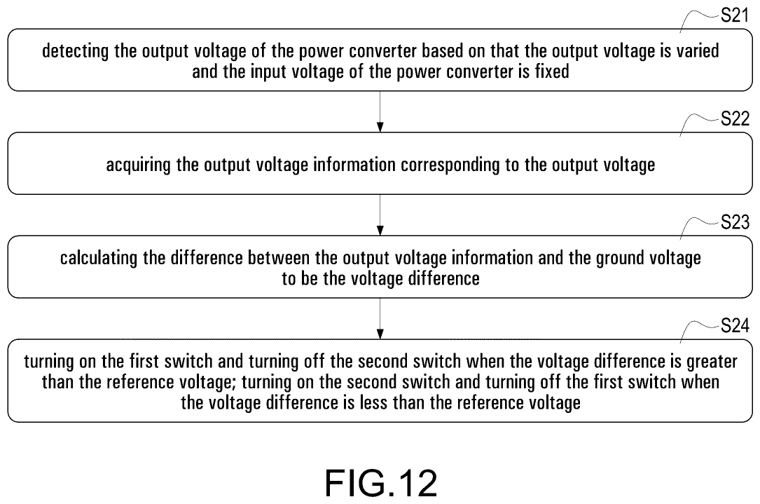

Please refer to FIG. 12, which shows a flowchart of a method of controlling the power converter according to a second embodiment of the present disclosure. The power converter includes a first switch Q_{H} and a second switch Q_{L}. The control method includes steps of: first, detecting an output voltage Vo of the power converter based on that the output voltage Vo is varied and an input voltage Vin of the power converter is fixed (step S21). Afterward, acquiring an output voltage information V_{HB}/V_{ZCD} corresponding to the output voltage Vo (step S22). Afterward, calculating a difference between the output voltage information V_{HB}/V_{ZCD} and a ground voltage V_{GND} to be a voltage difference Vdf (step S23). Finally, turning on the first switch Q_{H} and turning off the second switch Q_{L} when the voltage difference Vdf is greater than a reference voltage Vref; turning on the second switch Q_{L} and turning off the first switch Q_{H} when the voltage difference Vdf is less than the reference voltage Vref (step S24).

Incidentally, a voltage ratio between the output voltage information V_{HB} and the output voltage Vo is equal to a turns ratio between a primary-side winding Np and a secondary-side winding Ns of a transformer 10 of the power converter, or a voltage ratio between the output voltage information V_{ZCD} and the output voltage Vo is equal to a turns ratio between an auxiliary winding Na of the transformer and the secondary-side winding Ns.

In summary, the present disclosure has the following features and advantages:
1. Based on that the output voltage and the input voltage of the power converter are varied, by determining the relationship between the output voltage and the input voltage to minimize switching losses and increase the conversion efficiency of the power converter from converting the state where neither the first switch nor the second switch is turned on to the state where the first switch is turned on and the second switch is turned off, or the first switch is turned off and the second switch is turned under the DCM.
2. Based on that the output voltage is varied and the input voltage is fixed, by determining the relationship between the output voltage and the reference voltage to minimize switching losses and increase the conversion efficiency of the power converter from converting the state where neither the first switch nor the second switch is turned on to the state where the first switch is turned on and the second switch is turned off, or the first switch is turned off and the second switch is turned under the DCM.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A power converter comprising:
a transformer comprising a primary side and a secondary side, the primary side comprising a primary-side winding and an auxiliary winding, and the secondary side comprising a secondary-side winding,
a resonant circuit coupled to the primary-side winding, and the resonant circuit comprising a resonant capacitor and a resonant inductor, the resonant inductor comprising a magnetizing inductance and a leakage inductance,
a first switch and a second switch jointly connected at a node, and the node coupled to the resonant circuit to acquire a first output voltage information corresponding to an output voltage of the power converter,
an input detection circuit coupled to the first switch to acquire an input voltage information according to an input voltage of the power converter,
an output detection circuit comprising the auxiliary winding to acquire a second output voltage information corresponding to the output voltage, and
a controller configured to receive the first output voltage information, the second output voltage information, and the input voltage information to turn on or turn off the first switch and the second switch according to the first output voltage information, the second output voltage information, and the input voltage information.

2. The power converter as claimed in claim 1, wherein based on that the first switch and the second switch are turned off; when a difference between the input voltage information and the first output voltage information is greater than a difference between the first output voltage information and a ground voltage, the controller is configured to turn on the second switch and turn off the first switch; when the difference between the input voltage information and the first output voltage information is less than the difference between the first output voltage information and the ground voltage, the controller is configured to turn on the first switch and turn off the second switch.

3. The power converter as claimed in claim 1, wherein based on that the first switch and the second switch are turned off; when a difference between the input voltage information and the second output voltage information is greater than a difference between the second output voltage information and a ground voltage, the controller is configured to turn on the second switch and turn off the first switch; when the difference between the input voltage information and the second output voltage information is less than the difference between the second output voltage information and the ground voltage, the controller is configured to turn on the first switch and turn off the second switch.

4. The power converter as claimed in claim 1, wherein based on that the first switch and the second switch are turned off; when a difference between the first output voltage information and a ground voltage is greater than a reference voltage, the controller is configured to turn on the first switch and turn off the second switch; when the difference between the first output voltage information and the ground voltage is less than the reference voltage, the controller is configured to turn on the second switch and turn off the first switch.

5. The power converter as claimed in claim 1, wherein based on that the first switch and the second switch are turned off; when a difference between the second output voltage information and a ground voltage is greater than a reference voltage, the controller is configured to turn on the first switch and turn off the second switch; when the difference between the second output voltage information and the ground voltage is less than the reference voltage, the controller is configured to turn on the second switch and turn off the first switch.

6. The power converter as claimed in claim 1, wherein the input detection circuit comprises a first resistor and a second resistor; the first resistor and the second resistor configured to divide the input voltage to generate the input voltage information on the second resistor.

7. The power converter as claimed in claim 1, wherein a voltage ratio between the first output voltage information and the output voltage is equal to a turns ratio between the primary-side winding and the secondary-side winding.

8. The power converter as claimed in claim 1, wherein the output detection circuit further comprises a third resistor and a fourth resistor, and the third resistor and the fourth resistor coupled to the auxiliary winding; the third resistor and the fourth resistor configured to divide an auxiliary voltage on the auxiliary winding to generate the second output voltage information on the fourth resistor; wherein a voltage ratio between the auxiliary voltage and the output voltage is equal to a turns ration between the auxiliary winding and the secondary-side winding.

9. The power converter as claimed in claim 2, wherein the controller comprises:
a first differential amplifier configured to receive the input voltage information and the first output voltage information, and amplify a difference between the input voltage information and the first output voltage information to acquire a first voltage difference,
a second differential amplifier configured to receive the first output voltage information and the ground voltage, and amplify a difference between the first output voltage information and the ground voltage to acquire a second voltage difference, and
a comparator configured to receive the first voltage difference and the second voltage difference, and compare the first voltage difference with the second voltage difference to generate a control signal,
wherein when the control signal is in a high level, the control signal turns on the second switch and turns off the first switch; when the control signal is in a low level, the control signal turns on the first switch and turns off the second switch.

10. The power converter as claimed in claim 3, wherein the controller comprises:
a first differential amplifier configured to receive the input voltage information and the second output voltage information, and amplify a difference between the input voltage information and the second output voltage information to acquire a first voltage difference,
a second differential amplifier configured to receive the second output voltage information and the ground voltage, and amplify a difference between the second output voltage information and the ground voltage to acquire a second voltage difference, and
a comparator configured to receive the first voltage difference and the second voltage difference, and compare the first voltage difference with the second voltage difference to generate a control signal,
wherein when the control signal is in a high level, the control signal turns on the second switch and turns off the first switch; when the control signal is in a low level, the control signal turns on the first switch and turns off the second switch.

11. The power converter as claimed in claim 4, wherein the controller comprises:
a differential amplifier configured to receive the first output voltage information and a ground voltage, and amplify a difference between the first output voltage information and the ground voltage to acquire a voltage difference, and
a comparator configured to receive the voltage difference and the reference voltage, and compare the voltage difference with the reference voltage to generate a control signal,
wherein when the control signal is in a high level, the control signal turns on the second switch and turns off the first switch; when the control signal is in a low level, the control signal turns on the first switch and turns off the second switch.

12. The power converter as claimed in claim 5, wherein the controller comprises:
a differential amplifier configured to receive the second output voltage information and a ground voltage, and amplify a difference between the second output voltage information and the ground voltage to acquire a voltage difference, and
a comparator configured to receive the voltage difference and the reference voltage, and compare the voltage difference with the reference voltage to generate a control signal,
wherein when the control signal is in a high level, the control signal turns on the second switch and turns off the first switch; when the control signal is in a low level, the control signal turns on the first switch and turns off the second switch.

13. The power converter as claimed in claim 9, wherein the controller further comprises:
a register configured to receive the control signal, and store a high level or a low level of the control signal; when the register is triggered, the high level or the low level of the control signal is configured to control the first switch and the second switch to be turned on and turned off.

14. The power converter as claimed in claim 10, wherein the controller further comprises:
a register configured to receive the control signal, and store a high level or a low level of the control signal; when the register is triggered, the high level or the low level of the control signal is configured to control the first switch and the second switch to be turned on and turned off.

15. The power converter as claimed in claim 11, wherein the controller further comprises:
a register configured to receive the control signal, and store a high level or a low level of the control signal; when the register is triggered, the high level or the low level of the control signal is configured to control the first switch and the second switch to be turned on and turned off.

16. The power converter as claimed in claim 12, wherein the controller further comprises:
a register configured to receive the control signal, and store a high level or a low level of the control signal; when the register is triggered, the high level or the low level of the control signal is configured to control the first switch and the second switch to be turned on and turned off.

17. A method of controlling a power converter, the power converter comprising a first switch and a second switch, the method comprising steps of:
detecting an input voltage and an output voltage of the power converter based on that the input voltage and the output voltage are varied,
acquiring an input voltage information corresponding to the input voltage and acquiring an output voltage information corresponding to the output voltage,
calculating a difference between the input voltage information and the output voltage information to be a first voltage difference and calculating a difference between the output voltage information and a ground voltage to be a second voltage difference, and
turning on the second switch and turning off the first switch when the first voltage difference is greater than the second voltage difference; turning on the first switch and turning off the second switch when the first voltage difference is less than the second voltage difference.

18. The method of controlling the power converter as claimed in claim 17, wherein a voltage ratio between the output voltage information and the output voltage is equal to a turns ratio between a primary-side winding and a secondary-side winding of a transformer of the power converter, or a voltage ratio between the output voltage information and the output voltage is equal to a turns ratio between an auxiliary winding of the transformer and the secondary-side winding.

19. A method of controlling a power converter, the power converter comprising a first switch and a second switch, the method comprising steps of:
detecting an output voltage of the power converter based on that the output voltage is varied and an input voltage of the power converter is fixed,
acquiring an output voltage information corresponding to the output voltage,
calculating a difference between the output voltage information and a ground voltage to be a voltage difference, and
turning on the first switch and turning off the second switch when the voltage difference is greater than a reference voltage; turning on the second switch and turning off the first switch when the voltage difference is less than the reference voltage.

20. The method of controlling the power converter as claimed in claim 19, wherein a voltage ratio between the output voltage information and the output voltage is equal to a turns ratio between a primary-side winding and a secondary-side winding of a transformer of the power converter, or a voltage ratio between the output voltage information and the output voltage is equal to a turns ratio between an auxiliary winding of the transformer and the secondary-side winding.
